(19) United States
(12) Patent Application Publication
(10) Pub. No.: US 2016/0223126 A1
(43) Pub. Date: Aug. 4, 2016

(54) Document and Electronic Device Holder

(71) Applicant: Estela Mireles, Harlingen, TX (US)

(72) Inventor: Estela Mireles, Harlingen, TX (US)

(21) Appl. No.: 14/992,333

(22) Filed: Jan. 11, 2016

Related U.S. Application Data
(60) Provisional application No. 62/110,713, filed on Feb. 2, 2015.

(51) Int. Cl. F16M 11/04; A47B 23/04; H05K 5/02; F16M 11/22; H05K 5/00

(52) U.S. Cl. CPC F16M 11/046; F16M 11/22; H05K 5/0086; H05K 5/0204; A47B 23/043; F16M 2200/028

(57) ABSTRACT

A holder for adjustably supporting documents and electronic devices in an upright configuration. The document and electronic device holder includes a stand having a front side and a rear side, wherein each side includes a lower end and an upper end. A pair of supports extend outwards from the lower end of each side of the stand so as to support the stand in an upright configuration. An adjustable support is secured to the front side of the stand and can be raised and lowered on a track so as to allow a device to be disposed at the proper height for a user. The holder further includes a panel pivotally secured to the upper end of the front side of the stand and is movable between a stored configuration and an extended configuration for supporting a document or device having various sizes.

### CROSS REFERENCE TO RELATED APPLICATION

This application claims the benefit of U.S. Provisional Application No. 62/110,713 filed on Feb. 2, 2015. The above identified patent application is herein incorporated by reference in its entirety to provide continuity of disclosure.

### BACKGROUND OF THE INVENTION

The present invention relates to media holding devices. More specifically, the present invention provides a document and electronic device holder having a sliding stand and an extendable rear support for accommodating various sized media.

Many people struggle with neck, back, and shoulder pain because they are constantly hunched over their desks or straining their necks while reading documents, tablets, or other such media while using their computer. While the individual is reading the documents, tablets, and other media, it is typically resting on a flat surface or poorly propped at an angle. A common cause of these types of pain is forward head posture, which is due to looking downward for prolonged periods of time, instead of straight ahead. This can lead to a number of ailments, including headaches, vertebral degradation, and postural imbalance. Therefore, there is a need in the prior art for a device that allows documents, tablets, and other such media that a user is reading from directly at the eye level of the user, obviating the need for the user to look downward to read from the article.

Devices have been disclosed in the prior art that relate to document holders. These include devices that have been patented and published in patent application publications. These devices generally relate to stands having one or more slots or ledges on which to support a document, such as U.S. Published Patent Application Publication Number 2007/0045145, U.S. Pat. No. 6,435,466, U.S. Pat. No. 1,247,033, and U.S. Pat. No. 2,642,190.

These prior art devices have several known drawbacks. The prior art device fail to provide a device having an adjustable support and an extendable panel to allow a user to read documents and mobile electronic devices directly at the eye level of the user. The prior art devices provide a stand having a movable ledge on a front side thereof. However, these prior art devices fail to provide a media holding device having an extendable panel to allow for various sized media and a rear stand for storing additional media thereon.

In light of the devices disclosed in the prior art, it is submitted that the present invention substantially diverges in design elements from the prior art and consequently it is clear that there is a need in the art for an improvement to existing document and electronic device holders. In this regard the instant invention substantially fulfills these needs.

### SUMMARY OF THE INVENTION

In view of the foregoing disadvantages inherent in the known types of document and electronic device holders now present in the prior art, the present invention provides a new document and electronic device holder wherein the same can be utilized for providing convenience for the user when viewing documents and electronic devices hands-free at the desired height.

The document and electronic device holder comprises a stand having a front side and a rear side, wherein each side includes a lower end and an upper end. A pair of supports extend outwards from the lower end of each side of the stand so as to support the stand in an upright configuration. A third, adjustable support is secured to the front side of the stand and can be raised and lowered on a track so as to allow a device to be disposed at the proper height for a user. The holder further includes a panel pivotally secure to the upper end of the front side of the stand and movable between a stored configuration and an extended configuration for supporting a document or device having various sizes.

### BRIEF DESCRIPTIONS OF THE DRAWINGS

Although the characteristic features of this invention will be particularly pointed out in the claims, the invention itself and manner in which it may be made and used may be better understood after a review of the following description, taken in connection with the accompanying drawings wherein like numeral annotations are provided throughout.

FIG. 1 shows a perspective view of the front side of the document and electronic device holder.

FIG. 2 shows a perspective view of the rear side of the document and electronic device holder.

FIG. 3 shows a perspective view of the panel of the document and electronic device holder disposed in an extended configuration.

FIG. 4 shows a perspective view of the sliding mechanism of the document and electronic device holder.

### DETAILED DESCRIPTION OF THE INVENTION

Reference is made herein to the attached drawings. Like reference numerals are used throughout the drawings to depict like or similar elements of the document and electronic device holder. For the purposes of presenting a brief and clear description of the present invention, the preferred embodiment will be discussed as used for viewing documents and electronic devices hands-free at the desired height. The figures are intended for representative purposes only and should not be considered to be limiting in any respect.

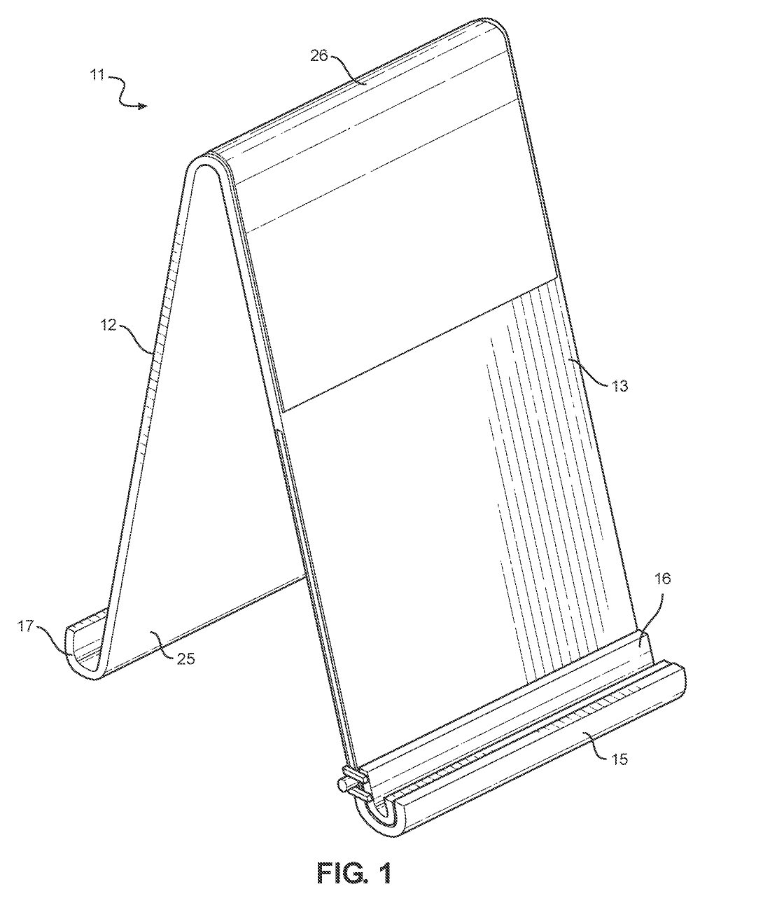

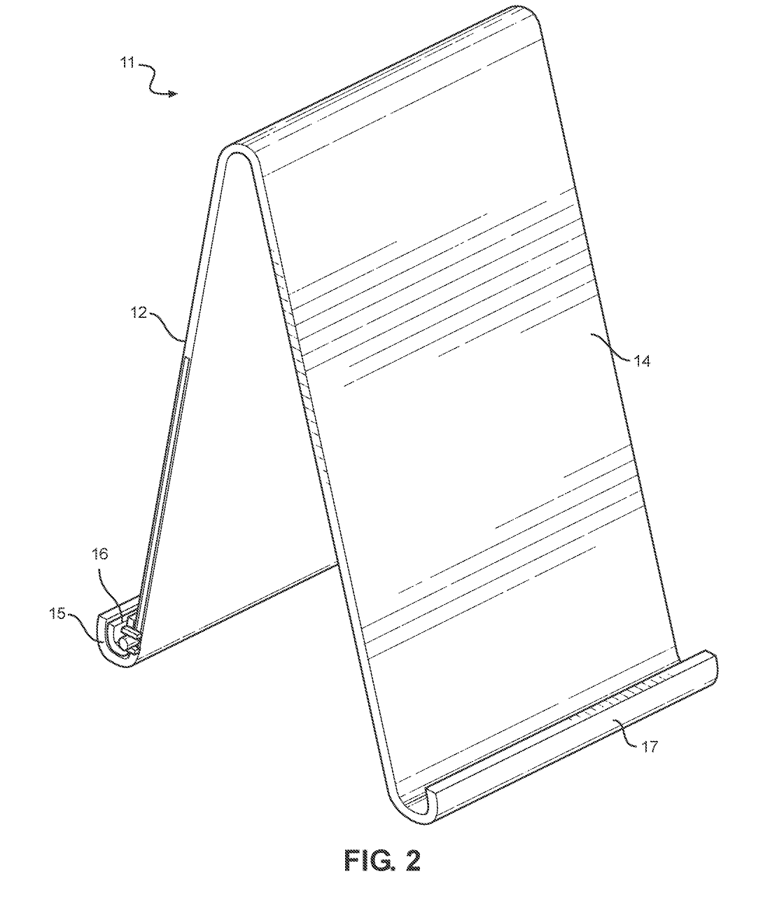

Referring now to FIGS. 1 and 2, there are shown perspective views of the front and rear side of the document and electronic device holder. The document and electronic device holder 11 includes a stand 12 having a front side 13 and a rear side 14, wherein each side includes a lower end 25 and an upper end 26. In the illustrated embodiment, the stand 12 comprises a V-shape and the sides 13, 14 are rectangular in shape, wherein the upper end 26 of the first side 13 is connected to the upper end 26 of the rear side 14 and the lower ends 25 are separated. The distance between the front side 13 and the rear side 14 increases towards the lower ends 25 thereof. Preferably, each side 13, 14 of the stand 12 is planar and disposed at an angle relative to a horizontal plane so as to allow the rear side of a document or electronic device rest flush thereagainst. In some embodiments, the upper ends 26 of the sides 13, 14 are pivotally secured to one another so as to allow a user to adjust the angle thereof.

The document and electronic device holder 11 further comprises a first support 15 and a second support 17 each extending outwards from the lower end 25 of the front and rear side 13, 14 of the stand 12 so as to support the stand 12 in an upright configuration. The second support 17 is further adapted to support the base of a document or electronic device in an upright configuration so as to allow it to rest against the rear side 14 of the stand 12. In the illustrated embodiment, the first and second supports 15, 17 comprise a hook shape. However, in alternate embodiments, the first and second support 15, 17 can comprise any suitable shape so as to support the stand 12 in an upright configuration.

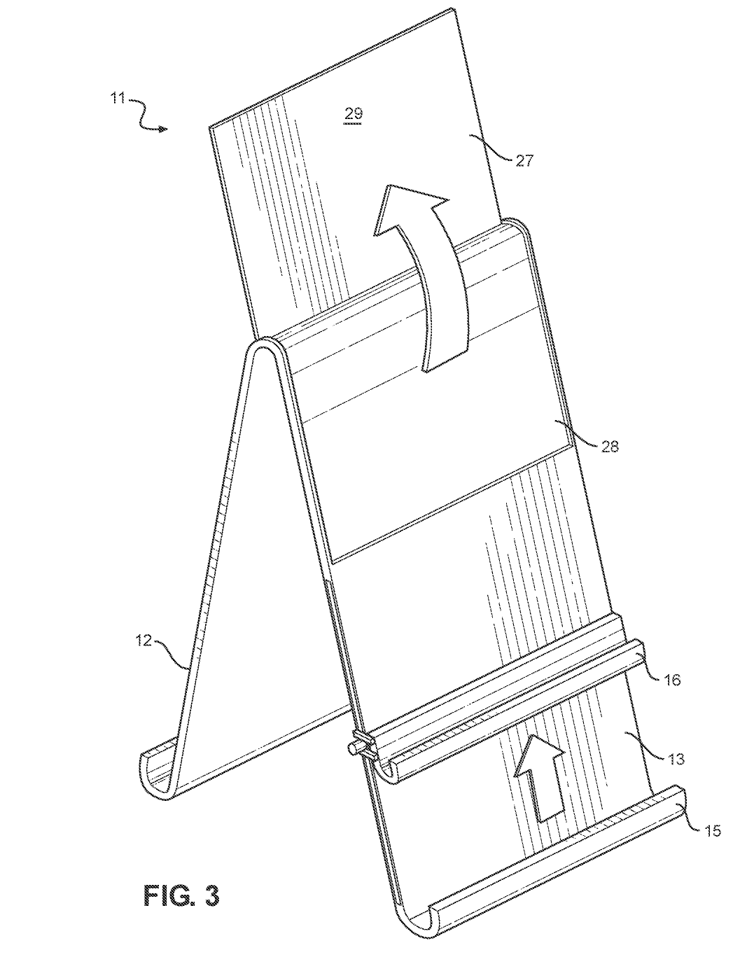

Referring now to FIG. 3, there is shown a perspective view of the panel of the document and electronic device holder disposed in an extended configuration. The document and electronic device 11 holder further comprises a panel 27 pivotally secured to the upper end 26 of the front side 13 of the stand 12. The panel 27 is movable between a stored configuration and an extended configuration, wherein in the extended configuration the panel 27 is adapted to support a document or electronic device extending above the upper end of the stand 12. In the extended configuration, the panel 27 is disposed above the upper end of the front side 13 of the stand 12, such that it is coplanar with the front side 13 of the stand 12 so as to provide a support for a rear side of a document or electronic device. The panel 27 is pivotally secured to the stand 12 via any suitable fastener that prevents the panel 27 from further rotating towards the rear side 14 once it is coplanar with the front side 13 of the stand 12. In the illustrated embodiment, the panel 27 comprises a rectangular shape, however, in alternate embodiments, the panel 27 comprises any suitable shape that provides additional vertical length to the stand 12, beyond the upper end thereof.

In the stored configuration, the lower surface 29 of the panel 27 rests flush against the front side 13 of the stand 12. In the illustrated embodiment, the front side 13 of the stand 12 comprises a recessed area 28 configured to receive the panel 27 in the stored configuration. Preferably, the recessed area 28 comprises a shape corresponding to the shape of the panel 27. In this way, the upper surface of the panel 27 aligns flush with the surface of the front side 13 of the stand 12.

A third support 16 is adjustably secured to the stand 12, preferably on the front side 13 thereof. The third support 16 is adapted to be raised and lowered between the upper and lower ends of the stand 12 and can be secured in a specific position thereon via a fastener. In the illustrated embodiment, the third support 16 comprises a hook shape so as to support the base of a document or electronic device. The third support 16 is further configured to rest within the first support 15 when lowered to the lower end of the stand 12. The adjustability of the third support 16 allows a user to place a document or electronic device thereon at a desirable viewing a height so as to avoid straining his or her neck, back, eyes, or the like.

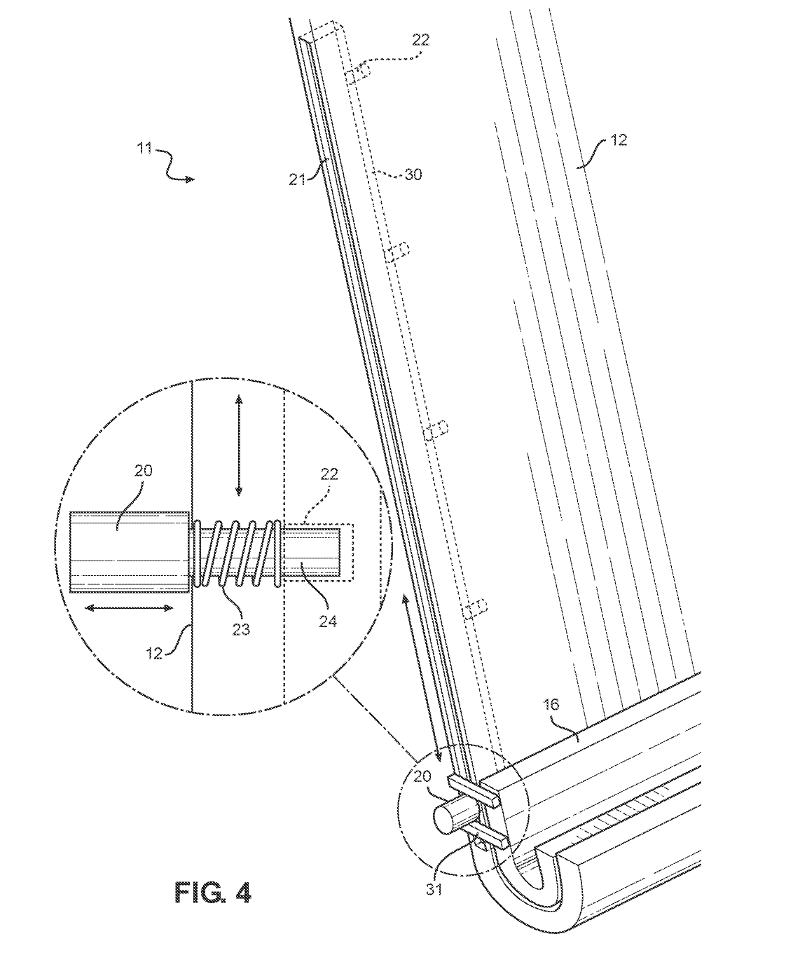

Referring now to FIG. 4, there is shown a perspective view of the sliding mechanism of the document and electronic device holder. Preferably, the third support 16 is adjustably secured to the front side 13 of the stand 12 via a sliding mechanism, wherein the sliding mechanism comprises a track 21 and a fastener 20 adjustably securing the third support 16 to the track. In the illustrated embodiment, the track 21 comprises a pair of channels wherein each channel is disposed on a lateral edge of the front side 13 of the stand 12. The track 21 further comprises a plurality of slots 22 disposed along the base 30 of each channel and configured to receive the fastener 20 therein. As the third support 16 is raised or lowered, the fastener 20 can be placed within the slot 21, locking the third support 16 therein.

In the illustrated embodiment, the fastener 20 comprises a pin having a first side and a second side 24, wherein the first side is configured to be pulled by the user and the second side 24 is configured to engage with a slot 22. As the user pulls the first end, the second end 24 is removed from the slot 22 so as to allow the pin to be moved up and down along the channel until the desired slot 22 is located. A spring 23 is secured to the pin, within the channel, so as to allow the pin to be moved laterally while also preventing the second end 24 of the pin from becoming removed from the track 21. When the user releases the first end of the pin, the pin can still be moved up and down until it automatically extends into a slot in which it becomes aligned with.

The third support 16 is movable along with the fastener 20 disposed on each lateral edge of the stand 12. Having the sliding mechanism disposed on the lateral edges of the stand 12 allow for multiple document and electronic device holder to be stacked on top of one another. In the illustrated embodiment, the third support 16 further comprises a pair of arms 31 extending perpendicularly from the lateral edge thereof, wherein a space is formed between the pair of arms 31. A portion of the fastener 20 is disposed within the space, between the arms 31, such that as the fastener 20 moves up and down along the track 21 the third support 16 is carried therewith. In other embodiments, the third support 16 can move along with the fastener via any suitable connection, such as a magnetic connection or the fastener 20 being integral to the third support 16.

It is therefore submitted that the instant invention has been shown and described in what is considered to be the most practical and preferred embodiments. It is recognized, however, that departures may be made within the scope of the invention and that obvious modifications will occur to a person skilled in the art. With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

I claim:

1) A document and electronic device holder, comprising:
a stand having a front side and a rear side, wherein the front side and the rear side each includes a lower end and an upper end;
a first support extending outwards from the lower end of the front side of the stand and configured to support the stand in an upright configuration;
an adjustable support secured to the front side of the stand, wherein the adjustable support is movable between the upper end and lower end of the front side of the stand;
a panel pivotally secure to the upper end of the front side of the stand and movable between a stored configuration and an extended configuration;
wherein in the stored configuration the panel rests flush against the front side of the stand and, in the extended configuration, the panel is disposed above the upper end of the front side of the stand to provide a support for a rear side of a document or electronic device.

2) The document and electronic device holder of claim 1, further comprising a second support extending outward from the lower end of the rear side of the stand and configured to support documents and electronic devices thereon.

3) The document and electronic device holder of claim 1, wherein the stand comprises a V-shape having the upper end of the first side connected to the upper end of the rear side, wherein a width between the front side and the rear side become wider towards the lower ends thereof.

4) The document and electronic device holder of claim 1, wherein the front side of the stand comprises a recessed area configured to receive the panel disposed in a stored configuration.

5) The document and electronic device holder of claim 1, wherein the first support and the adjustable support are hook shaped.

6) The document and electronic device holder of claim 1, wherein the adjustable support is adjustably secured to the front side of the stand via a sliding mechanism having a track disposed on each lateral edge of the stand and a fastener configured to slidably secure the adjustable support in a specific position on the front side of the stand.

7) The document and electronic device holder of claim 6, wherein the track comprises a channel and a plurality of slots disposed at a base of the channel and the fastener comprises a spring loaded pin movable along the channel and adapted to fit within each of the plurality of slots.

8) The document and electronic device holder of claim 6, wherein the fastener further comprises a pair of arms extending perpendicularly from each lateral edge of the adjustable support and configured to receive the spring loaded pin therethrough so as to slidably connect the adjustable support to the stand.
